(19) United States
(12) Patent Application Publication
(10) Pub. No.: US 2023/0076597 A1
(43) Pub. Date: Mar. 9, 2023

(54) PASSIVATED CONTACT SOLAR CELL AND FABRICATION METHOD FOR BACK PASSIVATION ASSEMBLY THEREOF

(71) Applicant: METAL INDUSTRIES RESEARCH & DEVELOPMENT CENTRE, Kaohsiung City 811 (TW)

(72) Inventors: Wei-Chen Tien, Chiayi City (TW); Yii-Der Wu, Kaohsiung City (TW); Chung-Sin Ye, Tainan City (TW); Cheng-Yuan Hung, Kaohsiung City (TW); Chun-Kai Huang, Kaohsiung City (TW)

(21) Appl. No.: 17/535,773

(22) Filed: Nov. 26, 2021

(30) Foreign Application Priority Data
Sep. 7, 2021 (TW) 110133200

(51) Int. Cl. H01L 31/0216; H01L 31/028; H01L 31/18

(52) U.S. Cl. CPC H01L 31/02167; H01L 31/028; H01L 31/1868

(57) ABSTRACT

A passivated contact solar cell includes a silicon substrate and a back passivation assembly which includes a tunnel oxide layer, an N-type doped polysilicon film and a cover layer. The tunnel oxide layer is formed on the silicon substrate, the N-type doped polysilicon film is formed on the tunnel oxide layer by PECVD and has a thickness between 30 nm and 100 nm, the cover layer is formed on the N-type doped polysilicon film. The N-type doped polysilicon film formed by PECVD allows the tunnel oxide layer to retain fine passivation ability so as to enhance conversion efficiency of the passivated contact solar cell.

### FIELD OF THE INVENTION

This invention relates to a passivated contact solar cell, and more particularly to a passivated contact solar cell having a back passivation assembly and a fabrication method for the back passivation assembly.

### BACKGROUND OF THE INVENTION

In solar cell, semiconductor substrate is used to absorb incident photons to create electron-hole pairs, electrons and holes in pairs are separated with each other by the action of electric field in the semiconductor substrate to accumulate at both sides of the semiconductor substrate, and both sides of the semiconductor substrate are connected by conducting wire to generate electric current. However, free electrons and holes excited by photons are easily recombined with each other, how to collect free electrons and holes before recombination is critical to enhance conversion efficiency of solar cell. Recently, a passivated contact solar cell having a passivation layer between a semiconductor substrate and a metal electrode is designed to lower carrier recombination resulted from contact between the semiconductor substrate and the metal electrode so as to improve the conversion efficiency of solar cell significantly. Owing to passivation ability of the passivation layer is proportional to the conversion efficiency of solar cell, it is important to improve passivation ability of the passivation layer for the future of a passivated contact solar cell with high conversion efficiency.

### SUMMARY

One object of the present invention is to form an N-type doped polysilicon film by plasma-enhanced chemical vapor deposition such that a tunnel oxide layer is protected with excellent passivation ability to enhance conversion efficiency of a passivated contact solar cell.

A passivated contact solar cell of the present invention includes a silicon substrate and a back passivation assembly. The back passivation assembly includes a tunnel oxide layer, an N-type doped polysilicon film and a cover layer. The tunnel oxide layer is formed on the silicon substrate, the N-type doped polysilicon film having a thickness between 30 nm and 100 nm is formed on the tunnel oxide layer by a plasma-enhanced chemical vapor deposition (PECVD) process, and the tunnel oxide layer is located between the silicon substrate and the N-type doped polysilicon film. The cover layer is formed on the N-type doped polysilicon film, and the N-type doped polysilicon film is located between the cover layer and the tunnel oxide layer.

A fabrication method for a back passivation assembly of a passivated contact solar cell comprising the steps of forming a tunnel oxide layer on a back surface of a silicon substrate; forming a N-type doped polysilicon film having a thickness between 30 nm and 100 nm on the tunnel oxide layer by a plasma-enhanced chemical vapor deposition (PECVD) process, the tunnel oxide layer is located between the silicon substrate and the N-type doped polysilicon film; and forming a cover layer on the N-type doped polysilicon film, the N-type doped polysilicon film is located between the cover layer and the tunnel oxide layer.

The N-type doped polysilicon film of the present invention is made through the PECVD process so as to protect the tunnel oxide layer from damage during forming of the N-type doped polysilicon film. Consequently, the tunnel oxide layer can exhibit excellent passivation ability to enhance conversion efficiency of the passivated contact solar cell.

### DESCRIPTION OF THE DRAWINGS

FIG. 1 is a cross-section view diagram illustrating a passivated contact solar cell in accordance with one embodiment of the present invention.

FIG. 2 is a cross-section view diagram illustrating a very high frequency (VHF) plasma deposition system in accordance with one embodiment of the present invention.

FIG. 3 is a flowchart illustrating a fabrication method for a back passivation assembly of the passivated contact solar cell in accordance with the present invention.

### DETAILED DESCRIPTION OF THE INVENTION

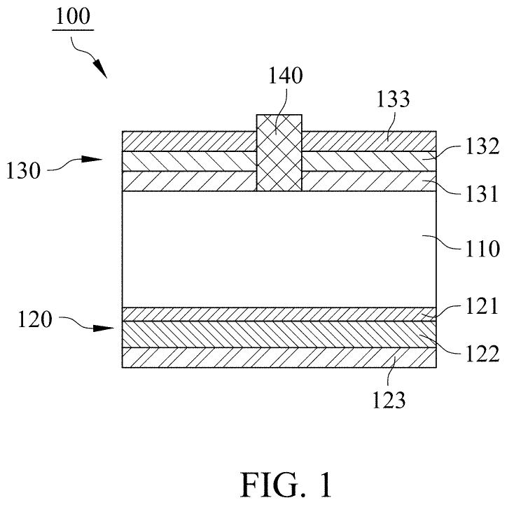

A passivated contact solar cell 100 in accordance with one embodiment of the present invention is shown in FIG. 1. The passivated contact solar cell 100 includes a silicon substrate 110, a back passivation assembly 120, a front passivation assembly 130 and a front electrode 140. The back passivation assembly 120 is located on a back surface of the silicon substrate 110, the front passivation assembly 130 and the front electrode 140 are located on an illuminated surface of the silicon substrate 100, and the front electrode 140 is passed through the front passivation assembly 130 to contact the silicon substrate 110.

The silicon substrate 110 is a P-type or N-type doped crystalline silicon substrate. Preferably, the silicon substrate 110 is an N-type doped crystalline silicon substrate with better power generation efficiency. The front passivation assembly 130 includes an aluminum oxide film 131, a silicon nitride film 132 and an anti-reflective coating 133. The aluminum oxide film 131 is formed on the illuminated surface of the silicon substrate 110, the silicon nitride film 132 is formed on the aluminum oxide film 131, and the anti-reflective coating 133 is formed on the silicon nitride film 132. The aluminum oxide film 131 and the silicon nitride film 132 are provided to reduce surface defects on the illuminated surface of the silicon substrate 110, moreover, the silicon nitride film 132 is an anti-reflective film. The anti-reflective coating 133 is used to further reduce reflectance and enhance incidence of incident light. Preferably, the illuminated surface of the silicon substrate 110 has a shape of triangular or quadrangular pyramid so as to lower light reflectance from the illuminated surface.

The front electrode 140 is screen printed on the front passivation assembly 130 and then burn through the front passivation assembly 130 by a sintering process. The photo-excited carrier accumulated on the illuminated surface can flow to the front electrode 140 to generate electric current.

With reference to FIG. 1, the back passivation assembly 120 includes a tunnel oxide layer 121, an N-type doped polysilicon film 122 and a cover layer 123. The tunnel oxide layer 121 is formed on the back surface of the silicon substrate 110 and the N-type doped polysilicon film 122 is formed on the tunnel oxide layer 121 such that the tunnel oxide layer 121 is located between the N-type doped polysilicon film 122 and the silicon substrate 110. The cover layer 123 is formed on the N-type doped polysilicon film 122 so the N-type doped polysilicon film 122 is located between the cover layer 123 and the tunnel oxide layer 121.

The tunnel oxide layer 121 is formed on the silicon substrate 110 by an oxidation process or an atomic layer deposition (ALD) process, and it is used to separate the silicon substrate 110 from a back electrode (not shown) and repair defects on the back surface of the silicon substrate 110. Thus, the tunnel oxide layer 121 can avoid carrier recombination on the silicon substrate 110 and improve conversion efficiency of the passivated contact solar cell 100. Preferably, the tunnel oxide layer 121 has a thickness between 0.1 nm and 3 nm so as to have improved carrier selectivity.

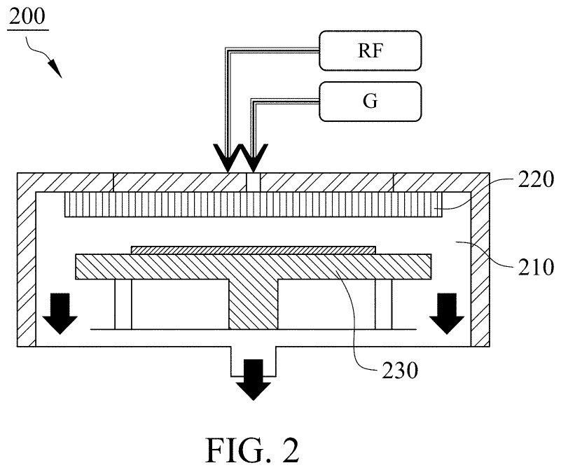

The N-type doped polysilicon film 122 is made on the tunnel oxide layer 121 through a plasma-enhanced chemical vapor deposition (PECVD) process. The N-type doped polysilicon film 122 can lower output resistance and make good contact with the back electrode (not shown). With reference to FIG. 2, in this embodiment, the PECVD process is operated in a very high frequency (VHF) plasma deposition system 200. The VHF plasma deposition system 200 includes a reactor 210, and a pump is provided to exhaust the reacted gas in the reactor 210 to keep the pressure in the reactor 210. The silicon substrate 110 is placed in the reactor 210, a reactant gas G is applied into the reactor 210, an electrode 220 in the reactor 210 receives a radio frequency signal from a radio frequency generator RF to ionize the reactant gas G into a plasma, and thus, the PECVD process can be performed on the silicon substrate 110 placed on a platform 230.

With reference to FIGS. 1 and 2, in this embodiment, a frequency of 40.68 MHz is applied in the PECVD process for the deposition of the N-type doped polysilicon film 122, the reactant gas G is a mixture gas of hydrogen (H₂) and silane (SiH₄) in a ratio between 1 to 2 and 1 to 5, the flow rate of the reactant gas G is from 2 to 5 sccm, the platform 230 is heated to 200° C., the pressure of the reactor 210 is 400 mtorr, and the radio-frequency power of the radio frequency generator RF is 35 mW/cm². The PECVD process operated with the parameters described above requires lower reaction temperature than conventional low-pressure chemical vapor deposition (LPCVD) and the plasma used in the PECVD process has low-ion bombardment energy, consequently, it is possible to protect the tunnel oxide layer 121 from heat damage during the formation of the N-type doped polysilicon film 122. Under high temperature exposure, elements of the N-type doped polysilicon film 122 may diffuse to the tunnel oxide layer 121 to lower the passivation ability of the tunnel oxide layer. Furthermore, ionization degree of the reactant gas G used in the PECVD process is high so as to produce the N-type doped polysilicon film 122 with high deposition rate, doping level and density.

The N-type doped polysilicon film 122 before a thermal treatment has a crystallinity between 30% and 50%, and the N-type doped polysilicon film 122 after the thermal treatment has a crystallinity between 80% and 100% and a sheet resistance between 50 Ohm/sq and 120 Ohm/sq. The thermal treatment is applied at 800 to 950° C.

The cover layer 123 is produced on the N-type doped polysilicon film 122 through chemical vapor deposition (CVD), physical vapor deposition (PVD) or atomic layer deposition (ALD) for protecting the N-type doped polysilicon film 122. The material of the cover layer 123 may be silicon nitride, silicon oxynitride, silicon oxide, aluminum oxide or hafnium oxide.

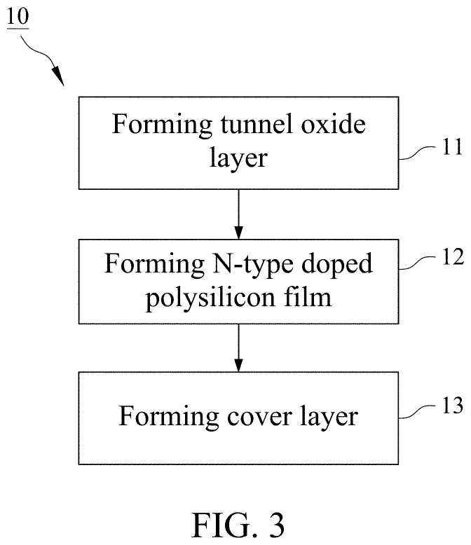

FIG. 3 is a flowchart of a fabrication method 10 for the back passivation assembly 120 of the passivated contact solar cell 100. The fabrication method 10 includes a step 11 of forming tunnel oxide layer, a step 12 of forming N-type doped polysilicon film and a step 13 of forming cover layer.

With reference to FIGS. 1 and 3, the tunnel oxide layer 121 is formed on the silicon substrate 110 through oxidation process or atomic layer deposition (ALD) in the step 11. In this embodiment, the tunnel oxide layer 121 having a thickness of 1.5 nm is formed on the back surface of the silicon substrate 110 by oxygen plasma surface treatment using the VHF plasma deposition system 200 shown in FIG. 2. A frequency of 40.68 MHz is applied in oxygen plasma surface treatment for forming the tunnel oxide layer 121, the treatment pressure is 1000 mtorr, the oxygen flow rate is 100 sccm, the radio frequency power is 60 mW/cm², and the platform 230 is heated to 150° C.

In the step 12, the N-type doped polysilicon film 122 is deposited on the tunnel oxide layer 121 by the PECVD process performed in the VHF plasma deposition system 200. In the PECVD process for formation of the N-type doped polysilicon film 122 having a thickness of 80 nm, a frequency of 40.68 MHz is applied, the reactant gas G is a mixture gas of hydrogen (H₂) and silane (SiH₄) in a ratio of 1 to 2, the flow rate of the reactant gas G is from 2 to 5 sccm, the temperature of the platform 230 is 200° C., the pressure in the reactor 210 is 400 mtorr, and the radio-frequency power of the radio frequency generator RF is 35 mW/cm². Then, the N-type doped polysilicon film 122 with 95% crystallinity and sheet resistance of 80 Ω/cm² is obtained after an annealing process at 900° C. for 1 hour.

In the final step 13, the cover layer 123 used to protect the N-type doped polysilicon film 122 is formed on the N-type doped polysilicon film 123 by chemical vapor deposition (CVD), physical vapor deposition (PVD) or atomic layer deposition (ALD). The cover layer 123 can be made of silicon nitride, silicon oxynitride, silicon oxide, aluminum oxide or hafnium oxide.

Analysis data show that the back passivation assembly 120 of the passivated contact solar cell 100 of this embodiment has a carrier lifetime of 2990 μs, an implied open-circuit voltage (Voc) of 707 mV, and a surface recombination current (j0) of 7.3 fA/cm². The back passivation assembly 120 with excellent performance actually can improve the conversion efficiency of the passivated contact solar cell 100 of the present invention.

The N-type doped polysilicon film 122 of the present invention is formed by the PECVD process so as to protect the tunnel oxide layer 121 from damage caused during the formation of the N-type doped polysilicon film 122. As a result, the tunnel oxide layer 121 has fine passivation ability to enhance the conversion efficiency of the passivated contact solar cell 100.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

What is claimed is:

1. A passivated contact solar cell comprising:
a silicon substrate; and
a back passivation assembly comprising:
a tunnel oxide layer formed on the silicon substrate;
a N-type doped polysilicon film formed on the tunnel oxide layer by a plasma-enhance chemical vapor deposition process, wherein the tunnel oxide layer is located between the silicon substrate and the N-type doped polysilicon film, and the N-type doped polysilicon film has a thickness between 30 nm and 100 nm; and
a cover layer formed on the N-type doped polysilicon film, wherein the N-type doped polysilicon film is located between the cover layer and the tunnel oxide layer.

2. The passivated contact solar cell in accordance with claim 1, wherein the N-type doped polysilicon film has a crystallinity between 80% and 100% and has a sheet resistance between 50 Ohm/sq and 120 Ohm/sq.

3. The passivated contact solar cell in accordance with claim 1, wherein the tunnel oxide layer has a thickness between 0.1 nm and 3 nm.

4. The passivated contact solar cell in accordance with claim 1, wherein the back passivation assembly has a carrier lifetime greater than or equal to 2990 μs and has an implied open-circuit voltage greater than or equal to 707 mV.

5. A fabrication method for back passivation assembly of passivated contact solar cell comprising:
forming a tunnel oxide layer on a back surface of a silicon substrate;
forming a N-type doped polysilicon film having a thickness between 30 nm and 100 nm on the tunnel oxide layer by a plasma-enhanced chemical vapor deposition process, wherein the tunnel oxide layer is located between the silicon substrate and the N-type doped polysilicon film; and
forming a cover layer on the N-type doped polysilicon film, wherein the N-type doped polysilicon film is located between the cover layer and the tunnel oxide layer.

6. The fabrication method in accordance with claim 5, wherein the plasma-enhanced chemical vapor deposition process is performed at a frequency of 40.68 MHz and a platform temperature between 50° C. and 200° C.

7. The fabrication method in accordance with claim 5, wherein a reactant gas is applied during the plasma-enhanced chemical vapor deposition process, and the reactant gas is a mixture gas of hydrogen and silane in a ratio between 1 to 2 and 1 to 5.

8. The fabrication method in accordance with claim 5, wherein a thermal treatment is applied to the N-type doped polysilicon film at 800 to 950° C. after forming the cover layer on the N-type doped polysilicon film.

9. The fabrication method in accordance with claim 5, wherein the tunnel oxide layer having a thickness between 0.1 nm and 3 nm is formed on the silicon substrate by an oxidation process or an atomic layer deposition process.
